(19) United States
(12) Patent Application Publication
(10) Pub. No.: US 2023/0320051 A1
(43) Pub. Date: Oct. 5, 2023

(54) ASSEMBLY-DISASSEMBLY TOOL

(71) Applicant: Optoma Corporation, New Taipei City (TW)

(72) Inventors: Ting-Yun Chi, New Taipei City (TW); Chia-Yu Li, New Taipei City (TW); Shih-Hung Hsu, New Taipei City (TW)

(73) Assignee: Optoma Corporation, New Taipei City (TW)

(21) Appl. No.: 18/183,957

(22) Filed: Mar. 15, 2023

(30) Foreign Application Priority Data
Mar. 29, 2022 (TW) 111112010

(51) Int. Cl. H05K 13/00; B25B 11/00

(52) U.S. Cl. CPC H05K 13/0061; B25B 11/002

(57) ABSTRACT

An assembly-disassembly tool is adapted for assembling and disassembling a lamp board. The assembly-disassembly tool includes a magnetic conductive member and a sliding module. The magnetic conductive member includes a through hole. When the disassembly tool is positioned on the lamp board, the through hole of the magnetic conductive member is aligned with an iron sheet of the light board. The sliding module including a magnet is slidably disposed above the magnetic conductive member along a direction parallel to a top surface of the magnetic conductive member. When the sliding module is located at a first position relative to the magnetic conductive member, the magnet is staggered with the through hole. When the sliding module slides to a second position relative to the magnetic conductive member, the magnet is aligned with the through hole and is configured to magnetically attract the iron sheet of the lamp board.

### CROSS-REFERENCE TO RELATED APPLICATION

This application claims the priority benefit of Taiwan application serial no. 111112010 filed on Mar. 29, 2022. The entirety of the above-mentioned patent application is hereby incorporated by reference herein and made a part of this specification.

### BACKGROUND

### Technical Field

The disclosure relates to an assembly-disassembly tool, and in particular, to an assembly-disassembly tool adapted for assembling and disassembling a lamp board.

### Description of Related Art

A display screen is conventionally formed with multiple lamp boards. How to conveniently assemble and disassemble lamp boards is a research direction in the art.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides an assembly-disassembly tool capable of conveniently assembling or disassembling a lamp board.

Other objectives and advantages of the invention will be further understood from the further technological features disclosed by the embodiments of the disclosure.

To achieve one of, a part of, or all of the objectives above or other objectives, an embodiment of the disclosure provides an assembly-disassembly tool adapted for assembling and disassembling a lamp board. The lamp board includes an iron sheet. The assembly-disassembly tool includes a magnetic conducive member and a sliding module. The magnetic conducive member includes a through hole. When the assembly-disassembly tool is positioned on the lamp board, the through hole of the magnetic conducive member is aligned with the iron sheet of the lamp board. The sliding module is slidably disposed above the magnetic conducive member along a direction parallel to a top surface of the magnetic conducive member, and the sliding module includes a magnet. When the sliding module is located at a first position relative to the magnetic conducive member, the magnet is staggered with the through hole. When the sliding module slides to a second position relative to the magnetic conducive member, the magnet is aligned with the through hole and is configured to magnetically attract the iron sheet of the lamp board.

In an embodiment of the disclosure, the assembly-disassembly tool further includes a box and a sliding rail disposed in the box. The sliding module is located at the box and slidably disposed on the sliding rail. The magnetic conducive member is located below the box.

In an embodiment of the disclosure, the assembly-disassembly tool further includes an elastic member disposed in the box and abutting against the sliding module so that the sliding module is normally located at the first position.

In an embodiment of the disclosure, the assembly-disassembly tool further includes a protection member that is rotatably disposed and a spring member connected to the protection member. The sliding module includes a stopper. In a process where the sliding module slides from the first position toward the second position, a position of the protection member is limited by an upper side of the stopper and the spring member is in a compressed state. When the sliding module is located at the second position, the upper side of the stopper leaves the protection member and the spring member releases elastic potential energy so that the protection member rotates to abut against a sidewall of the stopper to maintain the sliding module at the second position.

In an embodiment of the disclosure, the stopper is in a shape of inverted U.

In an embodiment of the disclosure, the assembly-disassembly tool further includes a cover covering the sliding module, and the cover includes a slot and an opening, wherein the slot extends along a sliding direction of the sliding module. The sliding module includes a protruding portion penetrating out of the cover from the slot, and a portion of the protection member penetrates out of the cover from the opening.

In an embodiment of the disclosure, the assembly-disassembly tool further includes a low-friction pad disposed between the sliding module and the magnetic conducive member. The sliding module contacts the low-friction pad, and a friction coefficient of the low-friction pad is less than or equal to 0.1.

In an embodiment of the disclosure, a material of the magnetic conducive member includes silicon steel or permalloy, or magnetic permeability of the magnetic conducive member is greater than or equal to 10²μ.

In an embodiment of the disclosure, when the magnet of the sliding module is aligned with the through hole and magnetically attracts the iron sheet of the lamp board, a distance between the magnet and the iron sheet ranges from 5 mm to 15 mm.

In an embodiment of the disclosure, the assembly-disassembly tool further includes a handle and an anti-slip pad. The handle is configured to cover a portion of the magnetic conducive member and is configured to hold the assembly-disassembly tool. The anti-slip pad is disposed below the magnetic conducive member.

Based on the above, the sliding module of the assembly-disassembly tool of the disclosure is slidably disposed above the magnetic conducive member along the direction parallel to the top surface of the magnetic conducive member, and the magnetic conducive member includes the through hole. When the assembly-disassembly tool is positioned on the lamp board, and the sliding module is located at the first position relative to the magnetic conducive member, the through hole of the magnetic conducive member is aligned with a first magnet of the lamp board, and the magnet is staggered with the through hole and the iron sheet. When the sliding module slides to the second position relative to the magnetic conducive member, the magnet of the sliding module is aligned with the through hole and the iron sheet and may magnetically attract the iron sheet of the lamp board. Therefore, a user may align the magnet with the through hole and the iron sheet to magnetically attract the iron sheet of the lamp board by adjusting a position of the sliding module. Hence, the lamp board may be moved. After the lamp board is placed at a specific position, the magnet is staggered with the through hole and the iron sheet. The magnet may be shielded by the magnetic conducive member so that the iron sheet of the lamp board is not magnetically attracted, and the lamp board may be separated from the assembly-disassembly tool.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an assembly-disassembly tool located at a first position according to an embodiment of the disclosure.

FIG. 2 is an exploded diagram of the assembly-disassembly tool of FIG. 1.

FIG. 3 is a schematic diagram after a box and a cover of the assembly-disassembly tool of FIG. 1 are hidden.

FIG. 4 is a schematic cross-sectional diagram of the assembly-disassembly tool of FIG. 1.

FIG. 5 is a schematic diagram of the assembly-disassembly tool of FIG. 1 located at a second position.

FIG. 6 is a schematic diagram after a box and a cover of the assembly-disassembly tool of FIG. 5 are hidden.

FIG. 7 is a schematic cross-sectional diagram of the assembly-disassembly tool of FIG. 5.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

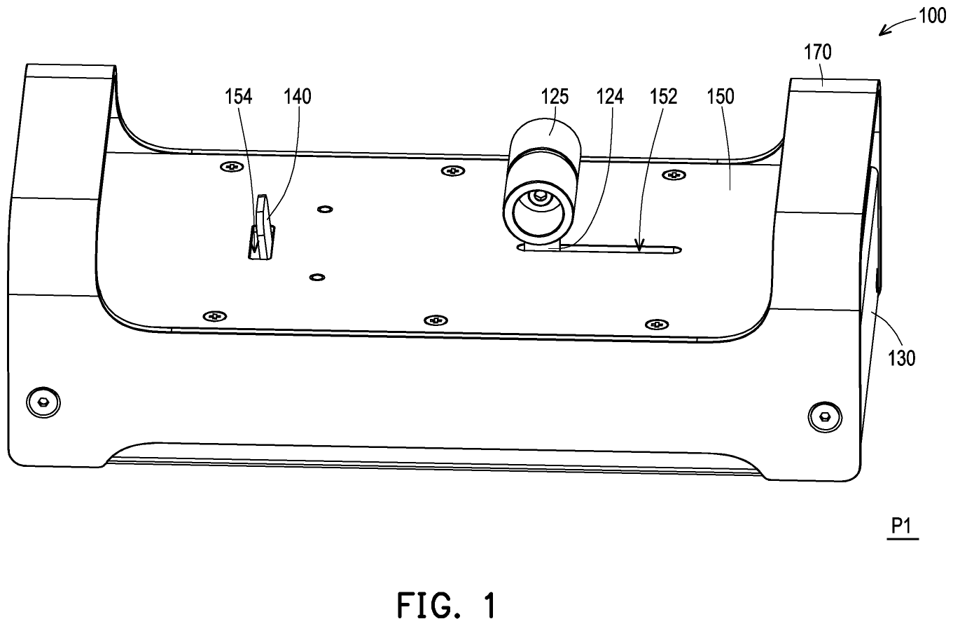

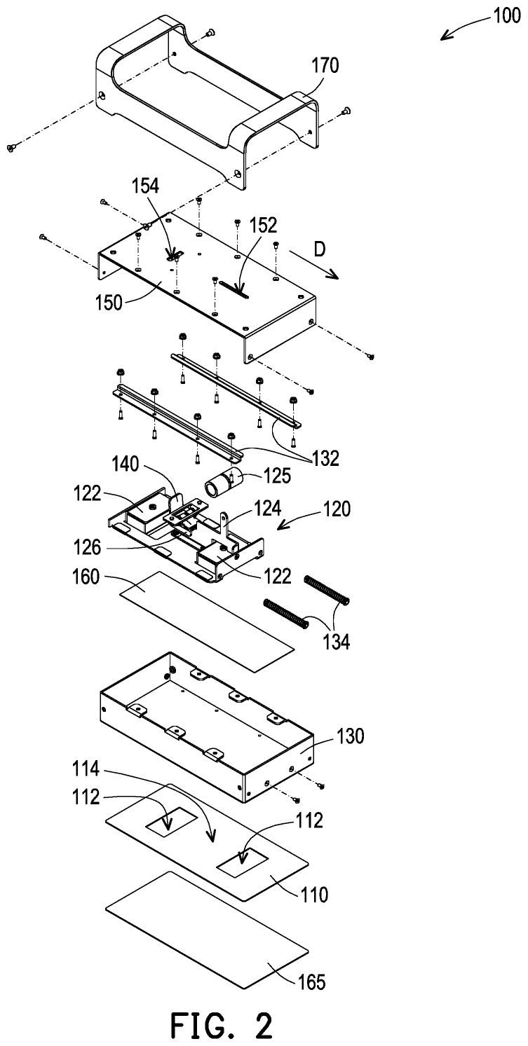

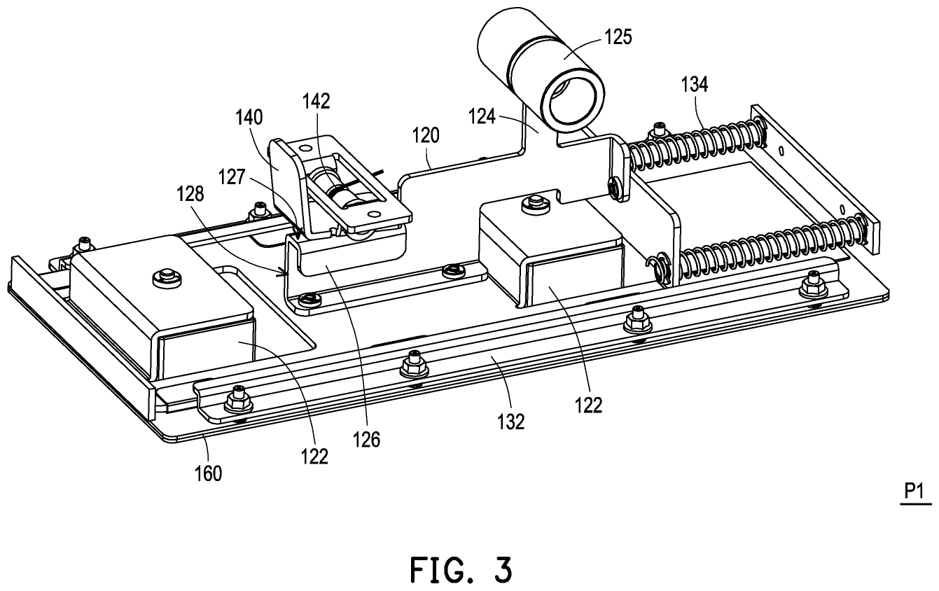

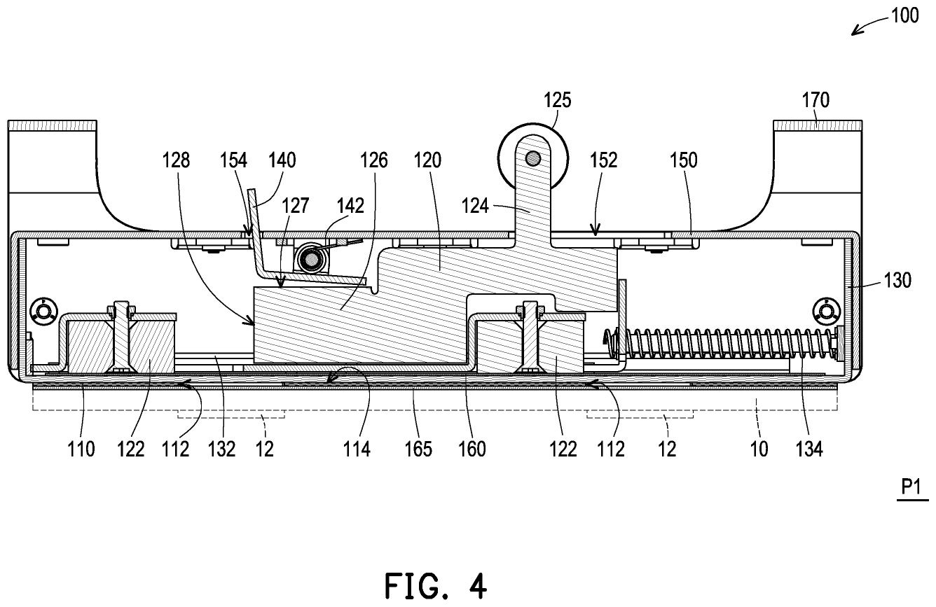

FIG. 1 is a schematic diagram of an assembly-disassembly tool located at a first position according to an embodiment of the disclosure. FIG. 2 is an exploded diagram of the assembly-disassembly tool of FIG. 1. FIG. 3 is a schematic diagram after a box and a cover of the assembly-disassembly tool of FIG. 1 are hidden. FIG. 4 is a schematic cross-sectional diagram of the assembly-disassembly tool of FIG. 1.

Referring to FIG. 1 to FIG. 4, an assembly-disassembly tool 100 of the embodiment is adapted for assembling and disassembling a lamp board 10 (illustrated with dotted lines in FIG. 4). The lamp board 10 includes an iron sheet 12 (illustrated with dotted lines in FIG. 4). As shown in FIG. 2, the assembly-disassembly tool 100 includes a magnetic conducive member 110 and a sliding module 120. In the embodiment, the lamp board 10 is, for example, a light-emitting diode (LED) lamp board.

A material of the magnetic conducive member 110 is, for example, a material with high permeability and well magnetostatic shielding. For example, the material of the magnetic conducive member 110 includes silicon steel or permalloy. Permalloy is a nickel-iron magnetic alloy with 20% iron and 80% nickel content and a magnetic permeability thereof is approximately 30,000μ. A silicon steel sheet is an iron-silicon alloy, and a magnetic permeability thereof is approximately 7,000 to 10,000μ. The material of the magnetic conducive member 110 is not limited thereto. In other embodiments, the material of the magnetic conducive member 110 may also be a ferromagnetic material, such as iron, steel, nickel, diamond, and the like. Or, magnetic permeability of the magnetic conducive member 110 is greater than or equal to 10²μ. In addition, the magnetic conducive member 110 includes a through hole 112.

The sliding module 120 is slidably disposed above the magnetic conducive member 110 along a direction (i.e. a sliding direction D) parallel to a top surface 114 of the magnetic conducive member 110, and the sliding module 120 includes a magnet 122.

In the embodiment, the assembly-disassembly tool 100 further includes a box 130 and a sliding rail 132 disposed in the box 130. The sliding module 120 is located at the box 130 and slidably disposed on the sliding rail 132. The magnetic conducive member 110 is located below a bottom wall of the box 130. A material of the box 130 is, for example, plastic; however, the material of the box 130 is not limited thereto.

In addition, the assembly-disassembly tool 100 may further selectively include a low-friction pad 160 disposed between the sliding module 120 and the magnetic conducive member 110. More specifically, the low-friction pad 160 is disposed on the bottom wall of the box 130, and the low-friction pad 160 is configured to reduce friction between the bottom wall of the box 130 and the sliding module 120. The low-friction pad 160 is, for example, Mylar; however, a type of the low-friction pad 160 is not limited thereto, as long as a friction coefficient of the low-friction pad 160 is less than or equal to 0.1.

When the assembly-disassembly tool 100 is positioned on the lamp board 10, the magnet 122 of the sliding module 120 may approach the bottom wall of the box 130 due to attraction to the iron sheet 12 of the lamp board 10. At this time, the sliding module 120 may contact the low-friction pad 160. Compared to the sliding module 120 directly contacting the bottom wall of the box 130, the sliding module 120 contacts the low-friction pad 160, thereby effectively facilitating the smooth sliding of the sliding module 120 relative to the box 130.

In addition, the assembly-disassembly tool 100 further includes an elastic member 134. The elastic member 134 is, for example, a compression spring; however, a type of the elastic member 134 is not limited thereto. The elastic member 134 is disposed in the box 130 and abuts against the sliding module 120 so that the sliding module 120 is operated as shown in FIG. 3 and FIG. 4 and is normally located at a first position P1.

In addition, the assembly-disassembly tool 100 further includes a cover 150 covering the sliding module 120 and the box 130. The cover 150 includes a slot 152 and an opening 154, wherein the slot 152 extends along the sliding direction D of the sliding module 120. The sliding module 120 includes a protruding portion 124 and a toggle button 125. The protruding portion 124 penetrates out of the cover 150 from the slot 152, and the toggle button 125 is assembled outside the cover 150 at the protruding portion 124 so that the user may conveniently hold and operate the toggle button 125.

In the embodiment, the assembly-disassembly tool 100 further includes a protection member 140 that is rotatably disposed and a spring member 142 connected to the protection member 140. A portion of the protection member 140 is located in the box 130, and the other portion (an upper end) of the protection member 140 penetrates out of the cover 150 from the opening 154. The spring member 142 is located between the box 130 and the cover 150. The spring member 142 is, for example, a torsion spring. An end of the spring member 142 is connected to the cover 150, and the other end of the spring member 142 is connected to the protection member 140. The spring member 142 is configured to drive the protection member 140 to rotate.

The sliding module 120 includes a stopper 126. In the embodiment, the stopper 126 is, for example, in a shape of inverted U to provide a platform at the upper side 127 of the stopper 126. As shown in FIG. 4, when the sliding module 120 is located at the first position P1, a position of the protection member 140 is limited by the upper side 127 of the stopper 126 and is unable to rotate downwards. The protection member 140 is in continuous contact with the upper side 127 of the stopper 126. A shape of the stopper 126 is not limited thereto.

In the embodiment, the assembly-disassembly tool 100 further includes a handle 170. The handle 170 is provided for the user to conveniently hold the assembly-disassembly tool 100. The handle 170 covers a portion of the cover 150, the box 130, and the magnetic conducive member 110. The toggle button 125 is exposed so that the user may conveniently operate the toggle button 125. In addition, the assembly-disassembly tool 100 further includes an anti-slip pad 165. The anti-slip pad 165 is disposed below the magnetic conducive member 110 so that the assembly-disassembly tool 100 may be more stably positioned on the lamp board 10.

In the embodiment, when the assembly-disassembly tool 100 is used to disassemble the lamp board 10, as shown in FIG. 4, the assembly-disassembly tool 100 is first positioned on the lamp board 10. At this time, the sliding module 120 is located at the first position P1 relative to the magnetic conducive member 110, and the through hole 112 of the magnetic conducive member 110 is aligned with the iron sheet 12 of the lamp board 10, and the magnet 122 is staggered with the through hole 112.

Since the magnetic conducive member 110 is located directly below the magnet 122 of the sliding module 120, the magnetic conducive member 110 separates the magnet 122 of the sliding module 120 and the iron sheet 12 of the lamp board 10. The magnet 122 of the sliding module 120 is shielded by the magnetic conducive member 110, and the magnetic attraction of the magnet 122 to the iron sheet 12 of the lamp board 10 is relatively weak, which may be viewed as that the magnet 122 is not able to magnetically attract the iron sheet 12 of the lamp board 10.

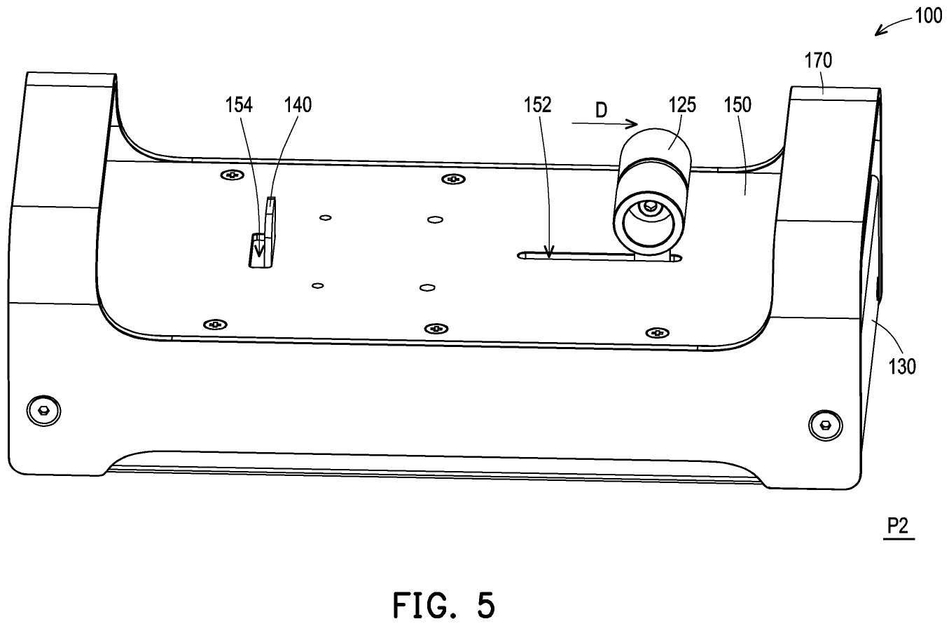

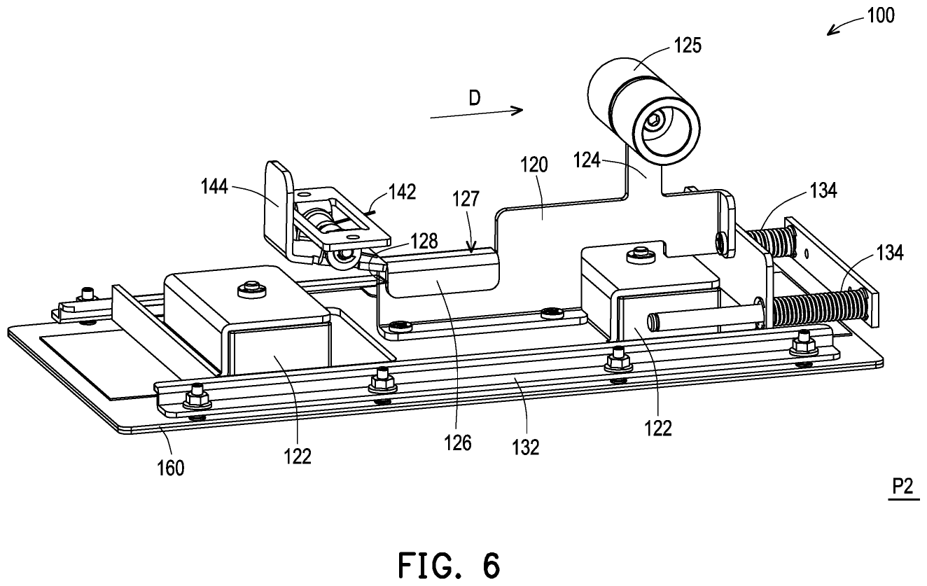

Next, FIG. 5 is a schematic diagram of the assembly-disassembly tool of FIG. 1 located at a second position. FIG. 6 is a schematic diagram after a box and a cover of the assembly-disassembly tool of FIG. 5 are hidden. Referring to FIG. 5 and FIG. 6, the toggle button 125 is moved so that the sliding module 120 slides from the first position P1 toward a second position P2.

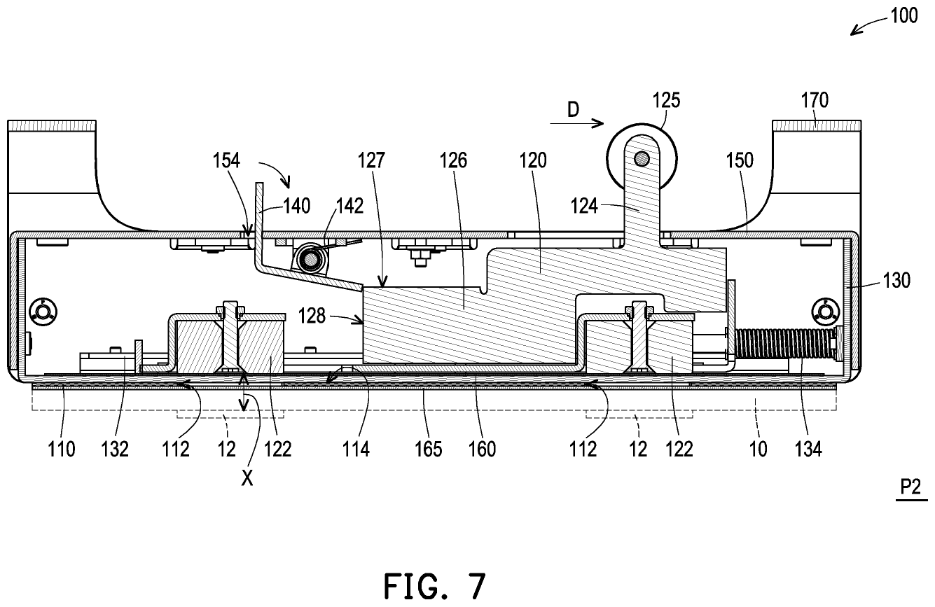

FIG. 7 is a schematic cross-sectional diagram of the assembly-disassembly tool of FIG. 5. Referring to FIG. 7, when the sliding module 120 slides to the second position P2 relative to the magnetic conducive member 110, the magnet 122 is aligned with the through hole 112 of the magnetic conducive member 110. That is, there is no magnetic conducive member 110 for shielding directly below the magnet 122 of the sliding module 120. The magnet 122 of the sliding module 120 may magnetically attract the iron sheet 12 of the lamp board 10. Hence, as long as the user holds the handle 170 of the assembly-disassembly tool 100, the lamp board 10 that is magnetically attracted may move along with the assembly-disassembly tool 100, and the lamp board 10 may also be disassembled.

As shown in FIG. 7, in the embodiment, when the magnet 122 of the sliding module 120 is aligned with the through hole 112 and magnetically attracts the iron sheet 12 of the lamp board 10, a distance X between the magnet 122 and the iron sheet 12 ranges from 5 mm to 15 mm. The distance is, for example, 10 mm, and well magnetic attraction may be provided. The distance X between the magnet 122 and the iron sheet 12 is not limited thereto.

It is worth noting that, in the embodiment, as shown in FIG. 4 and FIG. 7, in a process where the sliding module 120 slides from the first position P1 toward the second position P2, the protection member 140 may slide along the upper side 127 of the stopper 126, and rotation of the protection 140 is limited by the upper side 127 of the stopper 126. In this stage, the spring member 142 accumulates elastic potential energy. When the sliding module 120 moves to the second position P2, the upper side 127 of the stopper 126 leaves the protection member 140. The spring member 142 releases the elastic potential energy so that the protection member 140 rotates. The protection member 140 abuts against a sidewall 128 of the stopper 126 so that the sliding module 120 is maintained at the second position P2. With this design, it may be avoided that the sliding module 120 unexpectedly slides back to the first position P1 and thus affects the magnetic attraction.

In addition, since the stopper 126 is designed in the shape of inverted U, the protection member 140 may abut against the sidewall 128 of two vertical segments of the stopper 126, and an area of the protection member 140 abutting against the sidewall 128 of the stopper 126 may be increased. In addition, a weight of the stopper 126 may be reduced, and material cost may be reduced.

In addition, when the lamp board 10 is assembled, the user only needs to first position the assembly-disassembly tool 100 on the lamp board 10 and move the toggle button 125 to move the sliding module 120 from the first position P1 to the second position P2. After the assembly-disassembly tool 100 magnetically attracts the lamp board 10, the lamp board 10 is moved to a position where the lamp board 10 is required to be installed. Next, the protection member 140 is gently flicked counter-clockwise so that the protection member 140 leaves the sidewall 128 of the stopper 126 and returns above the upper side 127 of the stopper 126 to release the limitation of the position of the sliding module 120 by the protection member 140. Then, the sliding module 120 is pushed back to the first position P1 by the compressed elastic member 134 to release the magnetic attraction of the assembly-disassembly tool 100 to the lamp board 10. In an embodiment, without the elastic member 134, the user may also actively move the toggle button 125 in reverse to move the sliding module 120 back to the first position P1.

Note that, in the embodiment, when the sliding module 120 returns from the second position P2 to the first position P1, the magnet 122 of the sliding module 120 at the first position P1 is shielded by magnetic conducive member 110, and the magnetic attraction to the iron sheet 12 of the lamp board 10 is relatively weak. However, the iron sheet 12 of the lamp board 10 is still affected by some magnetic attraction of the magnet 122 of the sliding module 120. With this design, it may be avoided that the lamp board 10 suddenly drops from the assembly-disassembly tool 100 and the lamp board 10 is thus damaged.

In summary of the above, the sliding module of the assembly-disassembly tool of the disclosure is slidably disposed above the magnetic conducive member along the direction parallel to the top surface of the magnetic conducive member, and the magnetic conducive member includes a through hole. When the assembly-disassembly tool is positioned on the lamp board, and the sliding module is located at the first position relative to the magnetic conducive member, the through hole of the magnetic conducive member is aligned with the iron sheet of the lamp board, and the magnet is staggered with the through hole and the iron sheet. When the sliding module slides to the second position relative to the magnetic conducive member, the magnet of the sliding module is aligned with the through hole and the iron sheet and may magnetically attract the iron sheet of the lamp board. Therefore, the user may align the magnet with the through hole and the iron sheet to magnetically attract the iron sheet of the lamp board by adjusting the position of the sliding module. Hence, the lamp board may be moved. After the lamp board is placed at a specific position, the magnet is staggered with the through hole and the iron sheet. The magnet may be shielded by the magnetic conducive member so that the iron sheet of the lamp board is not magnetically attracted and the lamp board may be separated from the assembly-disassembly tool.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An assembly-disassembly tool, adapted for assembling and disassembling a lamp board, wherein the lamp board comprises an iron sheet, and the assembly-disassembly tool comprises:
a magnetic conducive member comprising a through hole, wherein, when the assembly-disassembly tool is positioned on the lamp board, the through hole of the magnetic conducive member is aligned with the iron sheet of the lamp board; and
a sliding module slidably disposed above the magnetic conducive member along a direction parallel to a top surface of the magnetic conducive member, and the sliding module comprises a magnet, wherein
when the sliding module is located at a first position relative to the magnetic conducive member, the magnet is staggered with the through hole; and
when the sliding module slides to a second position relative to the magnetic conducive member, the magnet is aligned with the through hole and is configured to magnetically attract the iron sheet of the lamp board.

2. The assembly-disassembly tool according to claim 1, further comprising a box and a sliding rail disposed in the box, wherein the sliding module is located at the box and slidably disposed on the sliding rail, and the magnetic conducive member is located below the box.

3. The assembly-disassembly tool according to claim 2, further comprising an elastic member disposed in the box and abutting against the sliding module so that the sliding module is normally located at the first position.

4. The assembly-disassembly tool according to claim 1, further comprising a protection member that is rotatably disposed and a spring member connected to the protection member, wherein the sliding module comprises a stopper, in a process where the sliding module slides from the first position toward the second position, a position of the protection member is limited by an upper side of the stopper, the spring member is in a compressed state, when the sliding module is located at the second position, the upper side of the stopper leaves the protection member, and the spring member releases elastic potential energy so that the protection member rotates to abut against a sidewall of the stopper to maintain the sliding module at the second position.

5. The assembly-disassembly tool according to claim 4, wherein the stopper is in a shape of inverted U.

6. The assembly-disassembly tool according to claim 4, further comprising a cover covering the sliding module, and the cover comprises a slot and an opening, wherein the slot extends along a sliding direction of the sliding module, and the sliding module comprises a protruding portion penetrating out of the cover from the slot, and a portion of the protection member penetrates out of the cover from the opening.

7. The assembly-disassembly tool according to claim 1, further comprising a low-friction pad disposed between the sliding module and the magnetic conducive member, wherein the sliding module contacts the low-friction pad, and a friction coefficient of the low-friction pad is less than or equal to 0.1.

8. The assembly-disassembly tool according to claim 1, wherein a material of the magnetic conducive member comprises silicon steel or permalloy, or a magnetic permeability of the magnetic conducive member is greater than or equal to 10²μ.

9. The assembly-disassembly tool according to claim 1, wherein, when the magnet of the sliding module is aligned with the through hole and magnetically attracting the iron sheet of the lamp board, a distance between the magnet and the iron sheet ranges from 5 mm to 15 mm.

10. The assembly-disassembly tool according to claim 1, further comprising a handle and an anti-slip pad, wherein the handle is configured to cover a portion of the magnetic conducive member and hold the assembly-disassembly tool, and the anti-slip pad is disposed below the magnetic conducive member.
